(19) United States
(12) Patent Application Publication
(10) Pub. No.: US 2007/0056713 A1
(43) Pub. Date: Mar. 15, 2007

(54) Integrated cooling design with heat pipes

(76) Inventors: Victor A. Chiriac, Phoenix, AZ (US); Tien Yu T. Lee, Phoenix, AZ (US)

Correspondence Address: INGRASSIA, FISHER & LORENZ, P.C., 7150 E. CAMELBACK ROAD, SUITE 325, SCOTTSDALE, AZ, 85251, US

(21) Appl. No.: 11/228,743

(22) Filed: Sep. 15, 2005

(51) Int. Cl. H05K 7/20

(52) U.S. Cl. 165/104.26; 165/104.33; 361/700

(57) ABSTRACT

Methods and apparatus are provided for a cooling system (100) for cooling a microelectronic device (102). The system includes a heat sink (104) and first and second heat pipes (106, 108). The heat sink (104) has a top side (114) and a bottom side (116). The top side (114) is coupled to the microelectronic device (102). The first and second heat pipes (106, 108) are embedded in the heat sink (104). The first heat pipe (106) is disposed along a first line (118). The second heat pipe (108) is disposed along a second line (120) that is not parallel to the first line (118) and each of the first and second heat pipes (106, 108) includes a portion located beneath the microelectronic device (102).

### FIELD OF THE INVENTION

The present invention generally relates to microelectronic devices, and more particularly relates to a system for cooling microelectronic devices.

### BACKGROUND OF THE INVENTION

As technology advances, the demand for more lightweight and compact electronic devices continues to increase. To keep up with the demand, smaller microprocessors configured to output more power have been implemented in these devices. These microprocessors allow the devices to perform complex operations at high speeds. During operation, however, the internal temperature of a device may rise to unacceptable levels as the power from the microprocessor is converted into heat. In some instances, the increased temperature may cause the device to function more slowly. In other cases, the device may malfunction. Thus, cooling systems are typically incorporated into the devices.

One type of cooling system includes a thermal interface material, a heat spreader, a single heat pipe, and a heat sink. A heat-generating item, (e.g. a microprocessor) is coupled to the heat spreader, and a thermal interface material is disposed therebetween. The heat pipe extends between the heat spreader and the heat sink. Although this system transfers heat away from the heat-generating item, it has drawbacks. For example, because the system only includes a single heat pipe, an insufficient amount of heat may be removed from the device if the heat pipe fails to operate. Additionally, the system has a limited cooling capability and does not efficiently cool devices including microprocessors, such as those described above.

Another type of cooling system employs a plurality of parallel heat pipes that unidirectionally removes heat from a heat-generating item. The heat pipes are parallel relative to one another and are either (1) all parallel to or (2) all perpendicular to the heat-generating item. Typically, a portion of the item is disposed over at least one of the heat pipes. Thus, the heat pipes closest to the heat-generating item will dissipate more heat than those heat pipes furthest from the item. However, if those heat pipes closest to the item fail to operate, the ability of the cooling system to remove heat may be significantly reduced.

Accordingly, it is desirable to provide a system that efficiently cools a microelectronic device. In addition, it is desirable for the system to be relatively lightweight, compact, and inexpensive to implement. Moreover, it is desirable for the system to continue to cool the device even when a portion of the system is inoperable.

### BRIEF DESCRIPTION OF THE DRAWINGS

Embodiments of the present invention will hereinafter be described in conjunction with the following drawing figures, wherein like numerals denote like elements, and

FIG. 1 is an isometric view of an exemplary cooling system;

FIG. 2 is a cross-sectional view of a portion of the exemplary cooling system depicted in FIG. 1 taken along line 2-2;

FIG. 3 is a cross-sectional view of an exemplary heat pipe that may be utilized in the cooling system depicted in FIG. 1;

FIG. 4 illustrates a first exemplary heat pipe configuration;

FIG. 5 illustrates a second exemplary heat pipe configuration;

FIG. 6 illustrates a third exemplary heat pipe configuration; and

FIG. 7 is an isometric view of another exemplary cooling system.

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

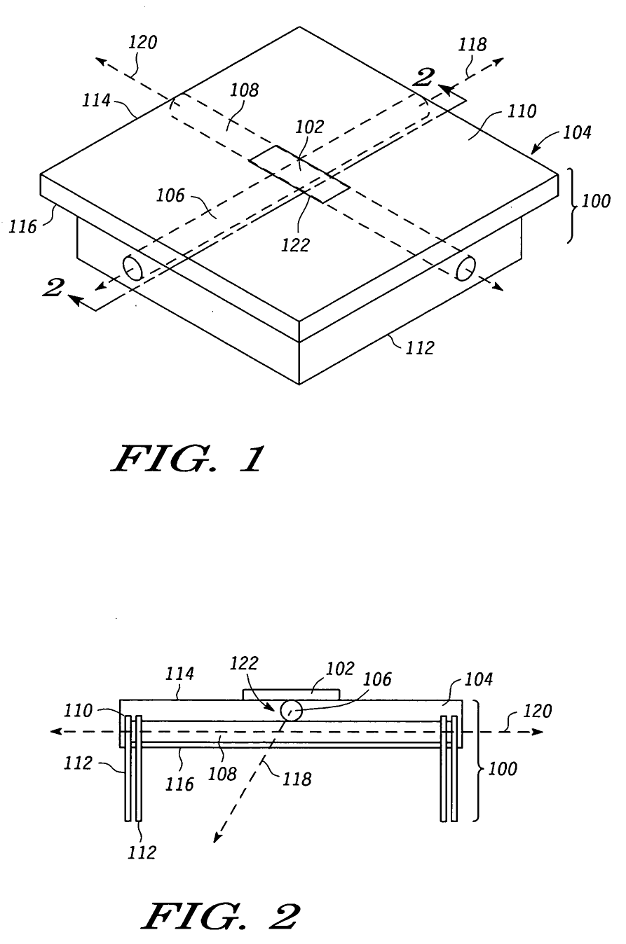

FIGS. 1 and 2 are isometric and cross-sectional views, respectively, of an exemplary cooling system 100. Cooling system 100 is coupled to an item 102 that generates heat, e.g., a microelectronic device that includes one or more integrated circuit chips, microprocessors, or similar devices. Cooling system 100 includes a heat sink 104, a first heat pipe 106, and a second heat pipe 108. Heat sink 104 and first and second heat pipes 106 and 108 are configured to cooperate with each other to absorb and dissipate heat that may be produced by item 102. Heat sink 104 includes a base plate 110 having a top side 114 to which item 102 is coupled and a bottom side 116 from which a plurality of fins 112 may extend. Base plate 110 and fins 112 are constructed of thermally conductive material; for example, aluminum, copper, or alloys thereof.

Fins 112 are configured to provide additional surface area from which heat from item 102 is dissipated. As briefly mentioned previously, fins 112 extend from bottom side 116 of base plate 110 and may be attached to or integrally formed as part of base plate 110. Fins 112 preferably extend from an outer periphery of base plate 110. Alternatively, fins 112 may reside inside the outer periphery of base plate 110, on either side of the base plate 110. Moreover, although a double row of fins 112 is shown in FIG. 2, fewer or more rows may alternatively be employed. First and second heat pipes 106 and 108 are configured to receive heat from base plate 110 and to radially transfer heat to one or more of fins 112. In this regard, at least a portion of each of the first and second heat pipes 106 and 108 is disposed beneath item 102.

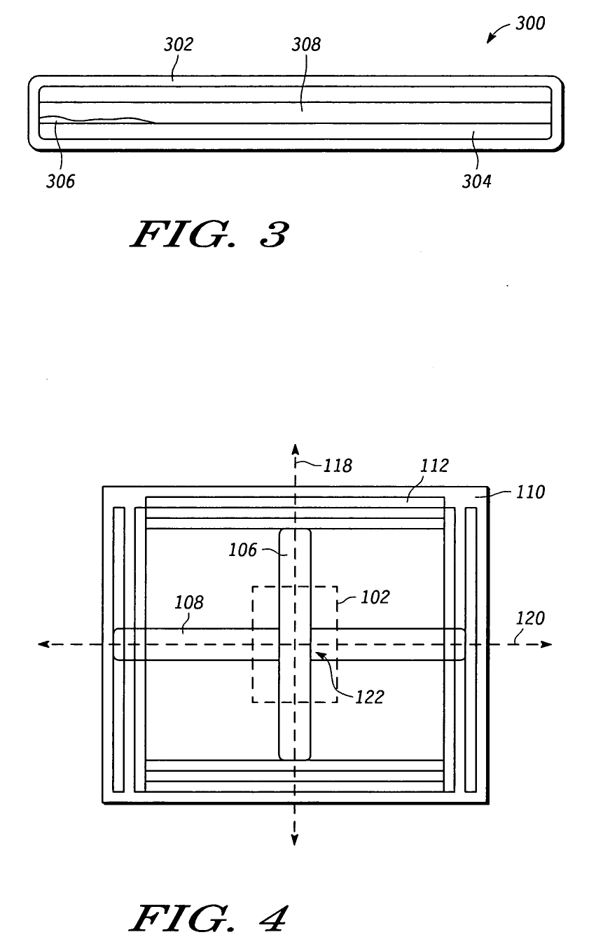

A cross section of an exemplary heat pipe 300 is illustrated in FIG. 3. Heat pipe 300 includes a tubular housing 302, a wick structure 304, and a fluid 306. Housing 302 is vacuum-sealed to provide an equilibrium between fluid 306 and gas present therein and has an inner peripheral surface that defines a cavity 308 within which wick structure 304 and fluid 306 are disposed. Wick structure 304 lines the inner peripheral surface of housing 302 and is made of porous material that is capable of absorbing fluid 306. An amount of fluid 306 that is sufficient to saturate wick structure 304 is employed. Although one particular embodiment of heat pipe is described herein, it will be appreciated that any one of numerous other conventional heat pipes may alternatively be employed.

Returning now to FIGS. 1 and 2, both heat pipes 106 and 108 are embedded between top and bottom sides 114 and 116, respectively, of base plate 110. Preferably, first and second heat pipes 106 and 108 are each disposed along first and second lines 118 and 120, respectively, that are not parallel and may be disposed in the same or different planes. Lines 118 and 120 may intersect or cross over each other, or alternatively, may merely meet at 122 to form a junction as in the letter “T”. At least a portion of each of the first and second heat pipes 106 and 108 is thermally coupled to at least one of fins 112.

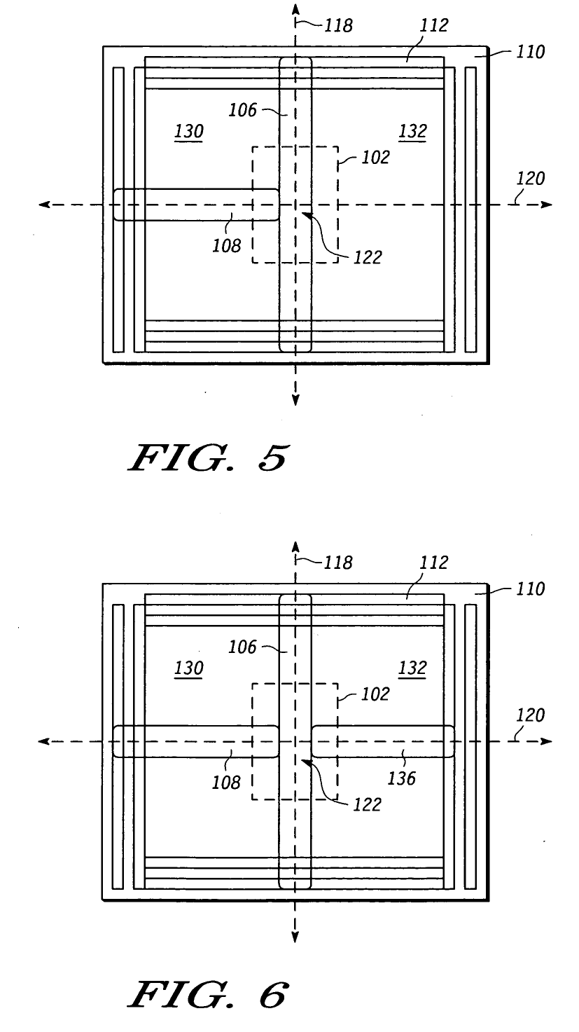

In one exemplary embodiment shown in FIGS. 2 and 4, first and second heat pipes 106 and 108 are each disposed along lines 118 and 120, respectively, which are in different planes. At least a portion of each heat pipe 106 and 108 is disposed beneath item 102 (shown in phantom in FIG. 4), and the ends of each heat pipe 106 and 108 contact fins 112. Additionally, heat pipes 106 and 108 may contact each other at junction 122.

Although the first and second heat pipes 106 and 108 are shown as being substantially similar in length, it will be appreciated that in other embodiments, the heat pipes may have unequal lengths. For example, as shown in FIG. 5, first heat pipe 106 extends substantially across a length of base plate 110 dividing base plate 110 into two sections 130 and 132. Second heat pipe 108 is shorter in length than first heat pipe 106 and is disposed in section 130. Heat pipes 106 and 108 may or may not be disposed in the same plane and may or may not contact each other.

Additionally, it will be appreciated that although FIGS. 4 and 5 show cooling system 100 as including two heat pipes, more heat pipes may additionally be employed. In one exemplary embodiment shown in FIG. 6, three heat pipes are used. In this regard, a third heat pipe 136 is disposed along line 120 in section 132. In another embodiment, third heat pipe 136 may not be disposed along line 118 and may be disposed along a different line (not shown).

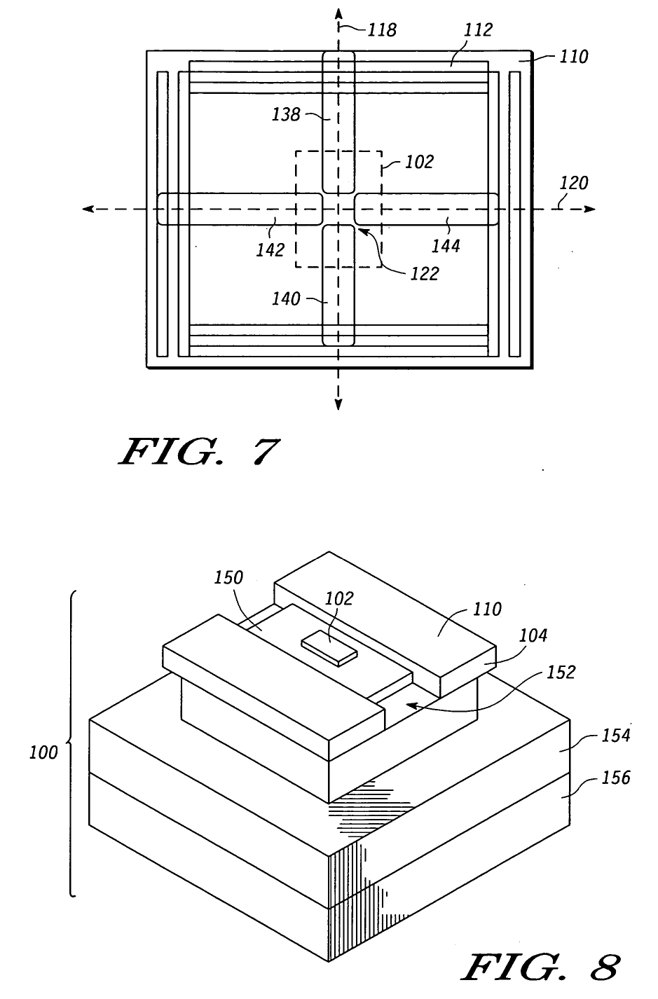

In still another exemplary embodiment, as shown in FIG. 7, four heat pipes 138, 140, 142, and 144 are employed. Here, two heat pipes 138 and 140 are disposed along line 118 and two heat pipes 142 and 144 are disposed along line 120. Each heat pipe 138, 140, 142, and 144 has an end that is located beneath item 102 at junction 122. Similar to previously described embodiments, each heat pipe 138, 140, 142, and 144 has another end that contacts at least one fin 112. Preferably, lines 118 and 120 are disposed in a single plane, however, it will be appreciated that they may alternatively be located in different planes.

Cooling system 100 may alternatively include additional features that cooperate with heat sink 104 to further reduce that amount of heat that may be present therein. For example, as shown in FIG. 8, cooling system 100 may additionally include a flange 150. Flange 150 is configured to increase thermal conductivity between item 102 and two or more heat pipes. In this regard, flange 150 is constructed of material that has an equal or greater thermal conductivity than does base plate 110. Suitable materials include, for example, copper and copper tungsten. Flange 150 may have any suitable configuration. In one exemplary embodiment, a groove or opening 152 is formed in base plate 110 and flange 150 is inserted therein, as shown in FIG. 7. Alternatively, flange 150 may be disposed between item 102 and base plate 110.

Also shown in FIG. 8, cooling system 100 may additionally include a mixing enclosure 154 and a fan 156. Enclosure 154 is preferably configured to provide a chamber within which heat from the heat pipes is mixed with cooler air provided by fan 156. In one exemplary embodiment, enclosure 154 is coupled to base plate bottom side 116 and fan 156 is coupled directly to enclosure 154. However, it will be appreciated that any other suitable configuration may alternatively be employed.

During operation, with reference to FIGS. 2-5, item 102 heats portions of the two or more heat pipes that are beneath item 102. The pressure increases in the heat pipe portions beneath item 102 causing fluid 306 in wick structure 304 to vaporize into a gas. The gas collects within cavity 308 and then travels radially outward to the outer periphery of base 110 toward fins 112. The cooler temperature of the sections of the heat pipes furthest away from item 102 causes the gas to transfer heat energy to fins 112 and to condense into fluid 306. Fluid 306 is absorbed by wick structure 304 and returns to the heat pipe sections closest to item 102 via capillary action. This cycle is preferably repeated to remove heat from item 102 thereby using a bidirectional, rather than unidirectional, lateral heat spreading technique to cool the item 102. Thus, unlike prior art designs, cooling system 100 does not fail when one of its heat pipes malfunctions.

Additionally, the inventors have discovered that the above-described method and system dissipate heat more effectively than other known designs. In one experiment, a die with four heat sources dissipating up to about 170 Watts was placed over a prior art cooling system having heat pipes disposed along parallel lines, and a similar die was placed over a cooling system 100 having heat pipes disposed along non-parallel lines, for example, in a cross configuration. The temperature of the die over the parallel heat pipe configuration was measured to be 99.3° C., while the temperature of the die over the non-parallel heat pipe configuration was advantageously lower and measured as 99.1° C. In another example, flanges 150 were inserted between the die and the heat pipes in the parallel and non-parallel configurations. The temperature of the die over the parallel heat pipes was measured at 93.0° C., while the temperature of the die over the non-parallel heat pipes was about 92.1° C.

The results from the experiments described above indicate that heat from a die disposed over a crossed heat pipe configuration is being removed more efficiently than in a parallel heat pipe configuration. Exposure of a die to lower temperatures reduces wear caused by thermal exposure and increases the useful life of the die. Thus, the crossed heat pipe configuration provides a simple solution for improving the thermal performance of a cooling system, while maintaining associated manufacturing costs within reasonable bounds.

A cooling system for cooling a microelectronic device has now been provided. In one exemplary embodiment, the system includes a heat sink and a first and a second heat pipes. The heat sink has a top side and a bottom side, where the top side is coupled to the microelectronic device. The first and a second heat pipes are embedded in the heat sink. The first heat pipe is disposed along a first line, and the second heat pipe is disposed along a second line that is not parallel to the first line. Each of the first and second heat pipes includes a portion located beneath the microelectronic device. In another exemplary embodiment, the first heat pipe divides the heat sink into a first section and a second section and the second heat pipe is embedded in the first section. In another exemplary embodiment, the heat sink further comprises a plurality of fins disposed proximate a periphery of the heat sink. Alternatively, at least a portion of each heat pipe is thermally coupled to at least one fin of the plurality of fins. The system may further comprise a third heat pipe disposed along said second line and in the second section, and the third heat pipe may include a portion located beneath the microelectronic device. The second and third heat pipes may contact the first heat pipe.

In still another exemplary embodiment, the first line and said second line are disposed in substantially the same plane. Alternatively, the system may further comprise a flange disposed between said heat sink and the microelectronic device. The flange amy comprise copper. In an alternate embodiment, at least a portion of the heat sink comprises a material selected from the group consisting of copper and aluminum. In yet another exemplary embodiment, the system may further comprise a fan coupled to the bottom side of the heat sink. In still yet another exemplary embodiment, the first and second heat pipes each comprise a tubular housing having an inner peripheral surface defining a cavity, a wick structure disposed on the inner peripheral surface of the tubular housing, and a fluid disposed in the cavity of the tubular housing in an amount sufficient to at least partially saturate the wick structure.

In another exemplary embodiment, a system for cooling a microelectronic device is provided that includes a heat sink, and first and second heat pipes. The heat sink has a base and a plurality of fins. The base includes a top side and a bottom side, where the top side is coupled to the microelectronic device, and the plurality of fins extend from the bottom side and are disposed proximate an outer periphery of the base. The first heat pipe is embedded in the base and disposed along a first line and has a first portion disposed beneath the microelectronic device and a second portion thermally coupled to at least one fin of the plurality of fins. The second heat pipe is embedded in the base along a second line that is not parallel to the first line, and the second heat pipe has a first portion disposed beneath the microelectronic device and a second portion thermally coupled to at least one fin of the plurality of fins.

In an alternative embodiment, a third heat pipe is disposed along said second line, the first heat pipe divides the heat sink into a first section and a second section, the second heat pipe is disposed in the first section, and the third heat pipe is disposed in the second section. In another alternative embodiment, the first and second heat pipes contact each other. The first and second lines may be disposed in substantially the same plane. Alternatively, the first and second lines are substantially perpendicular with respect to each other. In still another exemplary embodiment, a flange is coupled between the microelectronic device and the heat sink.

In still yet another exemplary embodiment, a method of cooling a microelectronic device is provided where the microelectronic device includes a heat sink and a first and a second heat pipe, the heat sink coupled to the microelectronic device, and the first and the second heat pipes embedded in the heat sink and having at least a portion disposed below the microelectronic device, the first heat pipe disposed along a first line, the second heat pipe disposed along a second line that is not parallel to the first line, each heat pipe including liquid disposed therein and a portion thermally coupled to at least one fin. In one embodiment, the method comprises the steps of transferring heat from the device to at least a portion of the first and second heat pipes disposed proximate the device, vaporizing the heat pipe liquid into a gas, in response to the heat from the device, and transporting the gas radially outward from the portions of the first and second heat pipes proximate the device to the outer periphery of the heat sink.

Alternatively, the heat sink further comprises a plurality of fins extending from the outer periphery thereof and the step of transporting the gas comprises transferring heat from the gas to at least one of the plurality of fins.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims and their legal equivalents.

What is claimed is:

1. A cooling system for cooling a microelectronic device, the system comprising:
a heat sink having a top side and a bottom side, said top side coupled to the microelectronic device; and
a first and a second heat pipe embedded in said heat sink, said first heat pipe disposed along a first line, said second heat pipe disposed along a second line that is not parallel to said first line and each of said first and second heat pipes including a portion located beneath the microelectronic device.

2. The system of claim 1, wherein said first heat pipe divides said heat sink into a first section and a second section and said second heat pipe is embedded in said first section.

3. The system of claim 1, wherein said heat sink further comprises a plurality of fins disposed proximate a periphery of said heat sink.

4. The system of claim 3, wherein at least a portion of each heat pipe is thermally coupled to at least one fin of said plurality of fins.

5. The system of claim 1, further comprising a third heat pipe disposed along said second line and in said second section, said third heat pipe including a portion located beneath the microelectronic device.

6. The system of claim 5, wherein said second and third heat pipes contact said first heat pipe.

7. The system of claim 1, wherein said first line and said second line are disposed in substantially the same plane.

8. The system of claim 1, further comprising a flange disposed between said heat sink and the microelectronic device.

9. The system of claim 8, wherein said flange comprise copper.

10. The system of claim 1, wherein at least a portion of said heat sink comprises a material selected from the group consisting of copper and aluminum.

11. The system of claim 1, further comprising a fan coupled to said bottom side of said heat sink.

12. The system of claim 1, wherein said first and second heat pipes each comprise:
a tubular housing having an inner peripheral surface defining a cavity;
a wick structure disposed on said inner peripheral surface of said tubular housing; and
a fluid disposed in said cavity of said tubular housing in an amount sufficient to at least partially saturate said wick structure.

13. A system for cooling a microelectronic device, the system comprising:
a heat sink having a base and a plurality of fins, said base including a top side and a bottom side, said top side coupled to the microelectronic device, and said plurality of fins extending from said bottom side and disposed proximate an outer periphery of said base;
a first heat pipe embedded in said base and disposed along a first line, said first heat pipe having a first portion disposed beneath the microelectronic device and a second portion thermally coupled to at least one fin of said plurality of fins; and
a second heat pipe embedded in said base along a second line that is not parallel to said first line, said second heat pipe having a first portion disposed beneath said microelectronic device and a second portion thermally coupled to at least one fin of said plurality of fins.

14. The system of claim 13, further comprising a third heat pipe disposed along said second line, wherein:
said first heat pipe divides said heat sink into a first section and a second section;
said second heat pipe is disposed in said first section; and
said third heat pipe is disposed in said second section.

15. The system of claim 13, wherein said first and second heat pipes contact each other.

16. The system of claim 13, wherein said first and second lines are disposed in substantially the same plane.

17. The system of claim 13, wherein said first and second lines are substantially perpendicular with respect to each other.

18. The system of claim 13, further comprising:
a flange coupled between the microelectronic device and said heat sink.

19. A method of cooling a microelectronic device including a heat sink and a first and a second heat pipe, the heat sink coupled to the microelectronic device, and the first and the second heat pipes embedded in the heat sink and having at least a portion disposed below the microelectronic device, the first heat pipe disposed along a first line, the second heat pipe disposed along a second line that is not parallel to the first line, each heat pipe including liquid disposed therein and a portion thermally coupled to at least one fin, the method comprising the steps of:
transferring heat from the device to at least a portion of the first and second heat pipes disposed proximate the device;
vaporizing the heat pipe liquid into a gas, in response to the heat from the device; and
transporting the gas radially outward from the portions of the first and second heat pipes proximate the device to the outer periphery of the heat sink.

20. The method of claim 19, wherein:
the heat sink further comprises a plurality of fins extending from the outer periphery thereof; and
the step of transporting the gas comprises transferring heat from the gas to at least one of the plurality of fins.
